(19) United States
(12) Patent Application Publication
(10) Pub. No.: US 2022/0115551 A1
(43) Pub. Date: Apr. 14, 2022

(54) BIFACIAL SPECTRUM SPLITTING PHOTOVOLTAIC MODULE

(71) Applicant: Arizona Board of Regents on Behalf of the University of Arizona, Tucson, AZ (US)

(72) Inventors: Raymond K. Kostuk, Tucson, AZ (US); Benjamin Chrysler, Tucson, AZ (US); Xuesen Tan, Tucson, AZ (US)

(21) Appl. No.: 17/602,975

(22) PCT Filed: Apr. 15, 2020
(86) PCT No.: PCT/US2020/028184

§ 371 Date: Oct. 11, 2021

Related U.S. Application Data
(60) Provisional application No. 62/833,925, filed on Apr. 15, 2019.

(51) Int. Cl. H01L 31/054; H01L 31/068; H01L 31/0693

(52) U.S. Cl. CPC H01L 31/0549; H01L 31/0693; H01L 31/0684

(57) ABSTRACT

A photovoltaic module comprises one or more spectrum splitting devices disposed adjacent a first side of the photovoltaic module; and a plurality of photovoltaic cells disposed adjacent a second side of the photovoltaic module opposite the first side and such that the photovoltaic cells are spaced from the one or more spectrum splitting devices, wherein at least one of the photovoltaic cells comprise a bifacial photovoltaic cell, wherein the one or more spectrum splitting devices are configured to selectively direct incident energy to one or more of the photovoltaic cells, and wherein a spatial configuration of the one or more spectrum splitting devices and the plurality of photovoltaic cells are configured based on an optimization parameter.

### FEDERAL FUNDING ACKNOWLEDGEMENT

This invention was made with government support under Grant No. 1041895, awarded by NSF. The government has certain rights in the invention.

### FIELD OF INVENTION

The present relates to the generation of electrical power using photovoltaic cells.

### BACKGROUND

In the past, photovoltaic (PV) cells have been widely used to convert sunlight into electricity. A plurality of cells may be located behind a glass sheet to form a PV module. PV modules may receive a fraction of all the light that enters the glass, both direct sunlight and diffuse skylight. However, the efficiency of conversion of the total amount of incident solar energy is not high; for example, little more than 20% conversion may be achieved in current commercial PV modules. This limitation arises in part because sunlight comprises a broad range of wavelengths, and conventional PV modules use a single semiconductor type. While any given semiconductor may convert with high efficiency at a given characteristic wavelength, it is less efficient at other wavelengths. In the relatively inefficient spectral regions of any given PV cell, only a small amount of the available solar energy may be converted into electricity.

A PV module with higher overall efficiency may be preferred over a conventional module, provided the overall cost is not increased so much as to offset the efficiency gain. Sunlight may potentially be converted into electricity with higher overall efficiency than is possible with any one semiconductor, by dividing the solar spectrum and using the different parts to power PV cells using different semiconductors, each cell being illuminated preferentially by those parts of the spectrum which it converts with highest efficiency. One approach taken in the past used different semiconductors stacked on top of each other, forming a multijunction cell. In such a multijunction cell, different spectral bands separate out by absorption and conversion as sunlight travels down through the stack. However, this multijunction approach has typically been limited to expensive semiconductors and manufacturing techniques. To reduce the overall cost of energy generation by this approach, typically a small multijunction cell has been used in conjunction with optics to collect a large area of direct sunlight and strongly focus it onto the small cell area. However, in such configurations, the diffuse component of sunlight, which is typically between 20% and 40% of the total input, is nearly all lost, and in many cases system cost is increased because of the additional focusing optics and dual axis tracker required.

Other methods to use combinations of semiconductors of smaller area and/or of lower cost have been proposed, in which sunlight is first passed through optics which spatially separate the spectrum, directing different parts of the spectrum to different separated cells to better match their different spectral responses.

In prior art, Newton (“Opticks” 1704) provides a glass prism to separate sunlight into distinct spectral bands by refraction. Such refractive dispersion has the advantage of unambiguous wavelength separation, with angular deviation decreasing monotonically as wavelength is increased, but has the disadvantage that the angular separation is small. In a patent application (US 2010/0095999 A1) “Ultra-high efficiency multi-junction solar cells using polychromatic diffractive concentrators”, inventor Menon proposes dispersion by a phase-plate and lens combination, the lenses focusing different wavelengths onto different laterally arranged cells. Diffraction by the phase plate gives higher angular spectral dispersion than a prism; however the design does not account for the fact that diffraction of any specific wavelength from the broad solar spectrum is generally in multiple orders, each being deflected (or directly transmitted) in a different direction. In another patent application, (US 20120318324 Al) “Laterally Arranged Multiple-Bandgap Solar Cells” 2012, inventors Ning and Caselli show laterally-arranged multiple bandgap solar cells and a notional depiction of dispersive concentrators positioned above to provide light to a surface of each of the cells, but do not provide specifics about the nature of the spectral separation, whether refractive or dispersive.

Zhang et al, Journal of Photonics for Energy, 2013, show a configuration with sunlight passing through a flat window of holographic lenses to PV cells of two different types. The lenses partially focus a band of the solar spectrum onto strips of cells of one type oriented perpendicular to the entrance window, while remaining light passes by to sheet of solar cells of another type oriented parallel to the entrance window.

Improvements are needed.

### SUMMARY

A photovoltaic module comprises one or more spectrum splitting devices disposed adjacent a first side of the photovoltaic module; and a plurality of photovoltaic cells disposed adjacent a second side of the photovoltaic module opposite the first side and such that the photovoltaic cells are spaced from the one or more spectrum splitting devices, wherein at least one of the photovoltaic cells comprise a bifacial photovoltaic cell, wherein the one or more spectrum splitting devices are configured to selectively direct incident energy to one or more of the photovoltaic cells, and wherein a spatial configuration of the one or more spectrum splitting devices and the plurality of photovoltaic cells are configured based on an optimization parameter.

The cost-per-watt of silicon photovoltaic (PV) modules has fallen by 80% in the last decade, but is only expected to decrease by another 15% in the next decade. This is due to a maturing manufacturing capability and the fact that silicon cells have already achieved 92% of the theoretical efficiency limit. Therefore, PV technologies based on traditional monofacial silicon cells are not expected to produce a significant reduction in cost-per-watt or cost-per-energy yield performance. Given the limitations in price reduction for conventional silicon panels, it is important to consider other PV technologies that achieve higher energy yield but can be manufactured using relatively inexpensive components and can be integrated into flat-panel modules compatible with conventional mounting and sun tracking hardware.

Several PV technologies have been studied that achieve high energy yield. Concentrating photovoltaic (CPV) systems focus direct sunlight onto multi junction solar cells that have high conversion efficiency. Since multi junction cells are manufactured using slow epitaxial growth processes, the cells are expensive and CPV systems must have high levels of concentration to be cost effective. In addition, CPV systems have been found to have lower performance than expected when operating in actual illumination conditions. One cause for the poor performance is that CPV systems do not convert diffuse sunlight which accounts for 15-40% even in characteristically sunny locations. CPV systems also require the use of dual-axis tracking systems that are more expensive than single-axis tracking and require more maintenance.

An alternative to CPV systems with tandem multi junction cells for achieving high conversion efficiency are spectrum-splitting photovoltaic (SSPV) systems. This approach uses a set of single-junction PV cells with different bandgap energies. Each PV cell converts light most efficiently within a limited range of the solar spectrum and is less efficient for the rest of the solar spectrum. An optical filter splits the solar spectrum into different spectral bands and directs each band to the solar cell with optimal spectral response to attain an overall higher module conversion efficiency. SSPV systems can achieve greater than 30% conversion efficiency when splitting the spectrum between two different bandgap energy PV cells. They can also operate efficiently at lower concentration levels and therefore work well with single-axis tracking. Volume holographic optical elements (VHOEs) are of particular interest for spectrum-splitting applications due to their efficient optical filtering properties and low cost. SSPV systems based on VHOEs also capture diffuse sunlight and can have form factors comparable to conventional silicon modules.

Conversion of ground-reflected light using bifacial photovoltaic (BFPV) cells is another technique to increase energy yield in a fixed collection region. BFPV systems have received greater interest in recent years and are expected to surpass 30% of the PV market share by 2025. BFPV systems use bifacial silicon solar cells that have electrical contact grids and PN-junctions designed to allow conversion from both the front and rear sides of the cell. The energy yield of a BFPV module can be improved by 10-50% depending on the characteristics of the ground surface and the module array configuration.

### BRIEF DESCRIPTION OF THE DRAWINGS

The following drawings show generally, by way of example, but not by way of limitation, various examples discussed in the present disclosure. In the drawings:

FIG. 1 shows an illustration of the bifacial spectrum-splitting photovoltaic system.

FIG. 2 shows an illustration of the volume holographic optical element (VHOE) used for spectrum splitting.

FIG. 3 shows a volume holographic lens.

FIG. 4 shows graphs for displaying data associated with volume holographic lenses.

FIG. 5 shows graphs for displaying data associated with volume holographic lenses.

FIG. 6 shows graphs for displaying collection factor data.

FIG. 7 shows a contour plot of the energy conversion efficiency for different illumination conditions.

FIG. 8 shows an illustration of power conversion efficiency for the direct component of sunlight as a function of incidence angle with respect to the module.

FIG. 9 shows graphs for displaying data associated with energy conversion efficiency.

FIG. 10 illustrates an example configuration of a photovoltaic module. As shown, a silicon cell is bifacial and a wide bandgap cell is not bifacial. It is understood that in other configurations various cells may be bifacial or not bifacial.

### DETAILED DESCRIPTION

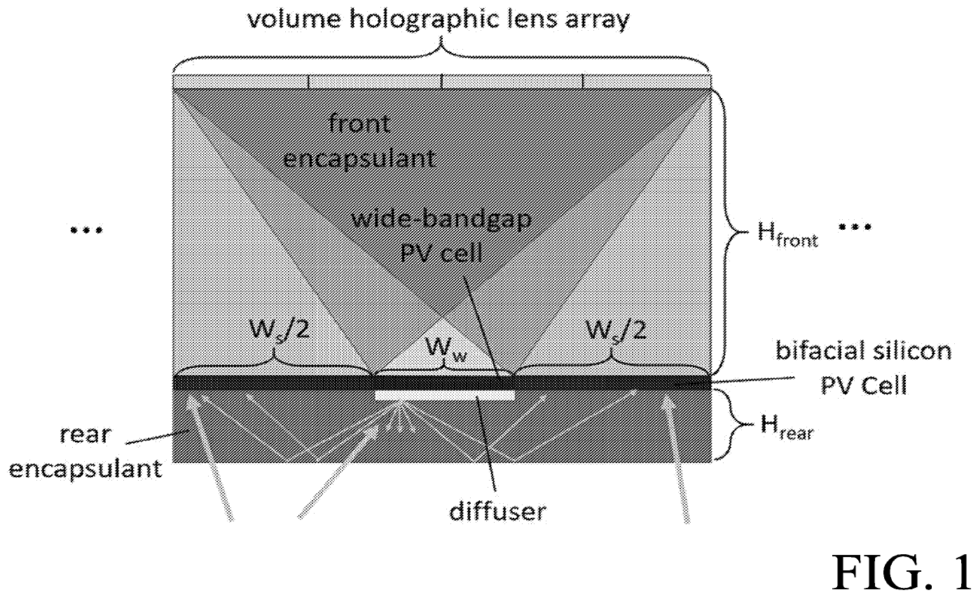

In the present disclosure, a bifacial spectrum-splitting photovoltaic (BF-SSPV) system is proposed that combines techniques used in SSPV and BFPV approaches, resulting in a system that attains higher energy yield than either method individually. A BF-SSPV system comprises an array of identical unit cells. A single unit cell is depicted in FIG. 1. Spectrum-splitting is accomplished in a manner similar to the system described by Vorndran et. al. with a volume holographic lens (VHL) array focusing and dispersing incident sunlight onto alternating rectangular strips of wide- and narrow-bandgap PV cells. In the design described in the present disclosure, a 22.5% efficient bifacial silicon cell with a 1.1 eV bandgap serves as the narrow-bandgap cell and the wide-bandgap cell is a 28.8% efficient monofacial GaAs with a 1.4 eV bandgap. Shorter wavelength light is dispersed onto the GaAs cell and longer wavelength light is dispersed onto the bifacial silicon cell. The holograms are designed for reconstruction at near normal incidence, therefore diffuse light which enters at non-normal incidence is not Bragg matched, passes through the hologram, and is also converted into electric power by the PV cells.

The BF-SSPV system has the additional benefit of converting rear-side illumination with the bifacial silicon cells. Rear-side illumination comprises light reflected from the ground surface, reflected from the surface of a nearby module, or scattered off the atmosphere and onto the rear side of the solar panel. Since the light collection on the rear side of the BF-SSPV module is limited by the fraction of the area which is covered by bifacial cells, light collection is enhanced by applying a diffusing scattering surface on the rear side of the GaAs cell. Some of the light that is scattered from the surface is reflected by total internal reflection (TIR), redirected onto the bifacial silicon, and converted to electrical power.

In the present disclosure a method for simulating and optimizing the annual energy yield (EYₜ) of the BF-SSPV system is developed. The EYₜ can be computed as a sum of direct, diffuse, and ground-reflected illumination components that are converted into electrical energy. First, the direct component is optimized by tuning the VHOE design parameters such as the hologram construction point-source locations, film thickness, and index modulation. Next, the rear-side and diffuse components are simulated and the EYₜ is computed for different illumination conditions. The analysis shows that the system converts 1010(kw·hr)/(yr·m\hat{ }2) in Tucson, Ariz., with dual-axis tracking and rear-side irradiance levels typical of utility scale mounting configurations. When accounting for losses due to single-axis tracking, the BF-SSPV generates 970(kw·hr)/(yr·m\hat{ }2). Only 10% of the 40(kw·hr)/(yr·m\hat{ }2) loss is due to decreased spectrum-splitting performance and the remaining loss is due to decreased irradiance from the cosine factor. The one-axis tracking energy yield is 45%, 26%, and 7% more than comparable monofacial silicon, bifacial silicon, and monofacial SSPV modules, respectively.

The EYₜ of the BF-SSPV system for different concentration ratios (CR), front aspect ratios (FAR), and rear aspect ratios (RAR) is evaluated where:

CR=(W_{w}+Wₛ)/W_{w} #(1)

FAR=H_{f}/(W_{w}+Wₛ) #(2)

RAR=Hᵣ/(W_{w}+Wₛ) #(3)

with W_{w} the width of the GaAs cell, Wₛ the width of the bifacial silicon cell, H_{f} the thickness of the front glass encapsulant, and Hᵣ the thickness of the rear glass encapsulant. Design tradeoffs between the system dimensions and the energy yield are analyzed to guide future work in balancing the size, cost, and performance of the system. The analysis shows that even very thin systems with FAR values as low as 0.25 or CR values as high as 8 can achieve the same energy yield as conventional monofacial modules with 30% conversion efficiency.

FIG. 1 shows an illustration of the bifacial spectrum-splitting photovoltaic system. A volume holographic lens array focuses and disperses light onto bifacial silicon and wide-bandgap GaAs photovoltaic cells for high conversion efficiency. The energy yield is enhanced by converting rear-side illumination with the bifacial silicon cells. A diffuser increases rear-side light collection by scattering light from the rear-side of the wide-bandgap cell onto the bifacial silicon.

Holographic Optical Element Optimization

Overview

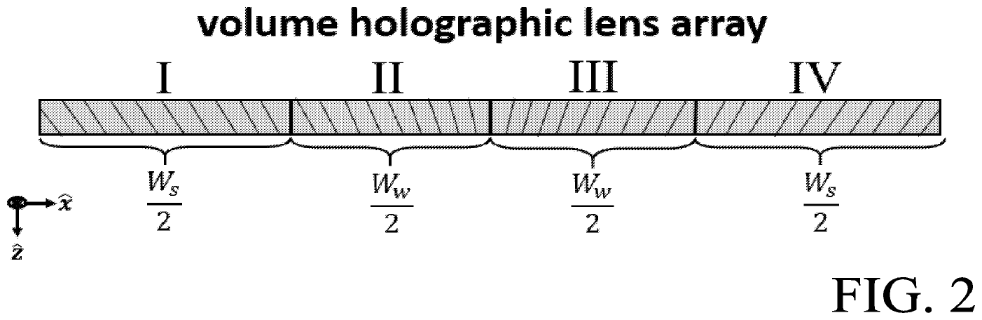

Within each unit cell, the VHOE comprises an array of VHLs as depicted in FIG. 2. VHLs I and II are designed to diffract and focus light towards the right side (i.e. +\hat{x}) of the unit cell, while VHLs III and IV diffract towards the left side (i.e. −\hat{x}) of the unit cell. VHLs I and IV are positioned above the bifacial silicon cell and diffract most efficiently in the spectral band of the GaAs cell (400 nm-875 nm) while VHLs II and III are positioned above the GaAs cell and diffract most efficiently in the spectral band of the silicon cell (875 nm-1200 nm). In this analysis we assume that each VHL is formed in dichromated gelatin (DCG) film using two-point sources with 532 nm laser light. VHLs I and IV are fabricated with thickness, d₁, and index modulation, Δn₁, and VHLs II and III are fabricated on a separate strip of film with thickness, d₂, and index modulation, Δn₂. The VHOE parameters directly affect the power conversion efficiency under direct sunlight (PCE_{d}) and the direct component of the EYₜ. In this section, an optimization routine is developed that determines the VHOE parameters that provide the highest PCE_{d} and EYₜ.

In previous SSPV design and optimization work by Vordran et. al. and Wu et. al. the Kogelnik Q-parameter was constrained to be at least 10 to ensure that the VHOE was diffracting in the thick grating regime. While a lower Q-number provides broader spectral bandwidth which is beneficial for spectrum-splitting, this constraint was used to ensure that all the diffracted light went into a single order and was directed to the intended PV cell. In order to more effectively balance the competing effects of the spectral bandwidth and degradation due to higher order diffraction, the holographic film thickness is determined by optimizing the PCE_{d} directly without constraining the Q-parameter of the VHOE. A further disadvantage of the Q-parameter constraint was that the holographic film thickness constrained the CR and FAR values of the system, since the dimensions of the system are related to the diffraction angles and the Q-parameter. By eliminating this constraint, designs that have practical advantages, such as higher CR or lower FAR values, can be investigated. These designs will then be evaluated with rigorous coupled wave analysis to determine issues with higher diffraction orders.

FIG. 2 shows an illustration of the volume holographic optical element (VHOE) used for spectrum splitting. The VHOE Comprises four volume holographic lenses (VHL), I, II, III, and IV, each with their own unique design constraints. VHLs I and II diffract toward the right (+\hat{x}) while VHLs III and IV diffract towards the left (−\hat{x}). VHLs I and IV diffract light within the spectral band of the wide-bandgap cell (0.4-0.875 um) and VHLs II and III diffract within the spectral band of the bifacial silicon (0.875-1.1 um).

Conversion of Direct Illumination

The PCE_{d} is determined by a combination of diffraction efficiency and ray tracing simulations. A model of the unit cell is set up in FRED non-sequential raytracing software. The total width of the unit cell is arbitrarily chosen and the remaining dimensions W_{w}, Wₛ, and H_{f} are scaled based on values of the CR and FAR. The VHOE is modeled by dividing it into 80 segments, in which the spatial frequency of each grating segment is determined based on the surface component of the grating vector, [symbol] (x). The number of segments is chosen to provide accurate raytracing resolution and account for the changing spectral diffraction efficiency, Tit (x,λ), across the surface of the lens, where i is the order of the diffracted beam. The spectral diffraction efficiency is computed using RCWA for 7 transmission orders and 7 reflected orders for each segment in the VHOE. Two methods for calculating the RCWA diffraction efficiency were utilized in the present disclosure. The computation was performed directly in Python during the VHOE optimization and using RSOFT electromagnetic simulation software during the final energy yield calculations and 3D angle of incidence calculations. The first method was used during optimization since it is ˜100× faster than RSOFT and more suitable for the computational burden of the optimization algorithm, but the second method was used during the final computation of the EYₜ for accuracy since it calculates TM polarization and 3D angles of incidence. Lastly, a broadband spectral source with spectrum, G(λ), was positioned above the VHOE.

First, a raytrace simulation was performed and used to obtain the spectral irradiance, Iⱼ (λ), incident on the j^{th} PV cell. The spectral irradiance is then used to compute the spectral optical efficiency, SOEⱼ (λ), defined as the ratio of the light on the j^{th} PV cell over the total incident spectrum:

SOEⱼ(λ)=Iⱼ(λ)/G(λ) #(4)

The PCE_{d} for direct sunlight is now obtained assuming an AM1.5 spectrum for direct sunlight generated in SMARTS2, AM1.5_{d} (λ):

$$P C {E}_{d} = {\sum }_{j} \frac{\int A M 1 . {5}_{d} ( λ ) \cdot {SOE}_{j} ( λ ) \cdot {SCE}_{j} ( λ ) \cdot d λ}{\int A M 1 . {5}_{d} ( λ ) \cdot d λ} \qquad \# ( 5 )$$

where the SCEⱼ(λ) is the spectral conversion efficiency for the j^{th} PV cell in the unit cell. The integral in the numerator is the power generated by the j^{th} PV cell and the integral in the denominator is the power in the spectrum.

Holographic Lens Construction Geometry

The hologram grating K-vector is used as a design parameter to achieve several important performance features. First, the hologram must provide sharp cutoffs between spectral bands. For this purpose, light at the “transition” wavelength is focused to the boundary between the GaAs and silicon PV cells, where the “transition” wavelength is the bandgap wavelength of the GaAs cell. Wavelengths shorter than the transition wavelength disperse across the GaAs cell and longer wavelengths disperse across the silicon cell. The transition wavelength and the coordinate point of the boundary between the two solar cells determines the surface component of the grating vector. The hologram must also provide high optical efficiency within specific spectral bands. This can be achieved by adjusting the slant angle of the grating vector to diffract normally incident light most efficiently for a given wavelength in the center of the spectral band. The K-vector that satisfies both these conditions across the entire aperture of the VHL is the target grating K-vector, [symbol] ₜ(x).

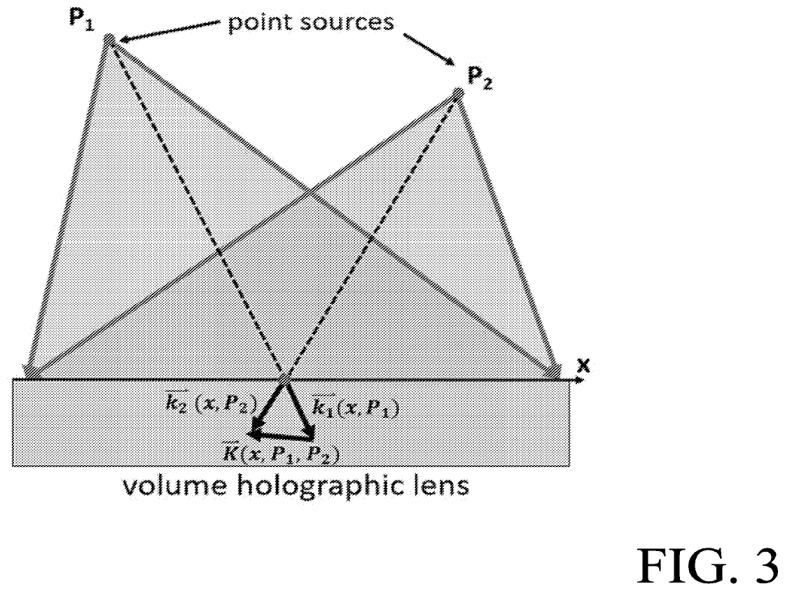

FIG. 3 shows a volume holographic lens. Volume holographic lenses are formed through interference of two point sources of monochromatic light. The grating K-vector varies as a function of the position along the aperture, x, and the position of the two point sources P₁ and P₂. The position of the point sources are optimized to maximize diffraction efficiency and minimize aberrations.

In practice, holograms are typically manufactured using a “two-point source” construction geometry as illustrated in FIG. 3. For the VHLs in this system, the focusing only occurs in one dimension, so each “point source” is actually a “line source”, which can be generated by focusing with a cylindrical lens. The grating K-vector produced by point sources P₁ and P₂ is given by:

[symbol]

(x,P₁,P₂)= [symbol] (x,P₁)− [symbol] ₂(x,P₂) #(6)

Since holographic materials have sensitivities in the visible range and the transition wavelength lies in the infrared, the hologram must be fabricated with light at a different wavelength than the focusing wavelength. As a result, [symbol] ₜ(x) cannot be fabricated without error using a two-point source construction method. Errors in the constructed K-vector will result in aberrations that decrease the quality of the spectral band separation characteristics and reduce the diffraction efficiency across the aperture of the VHL. Both of these effects limit the PCE_{d} of the system. To overcome this limitation, a robust algorithm is developed that determines the point source locations that minimize the error Δ between the constructed K-vector and the target K-vector:

Δ=∥ [symbol] (x,P₁,P₂)− [symbol] ₜ(x)∥₂ #(7)

The optimization is performed in Python using the optimize.minimize function in SciPy. This process is repeated for each of the four VHLs in the unit cell of the VHOE. The K-vector formed using the resulting point sources is used in the subsequent simulation and optimization of the VHOE.

Film Thickness and Index Modulation

Each VHL must diffract light efficiently across its spectral band to obtain high PCE_{d} which is a function of the hologram film thickness and effective refractive index modulation values that the recording material can have. In this stage of the optimization, the values of d₁, Δn₁, d₂, and Δn₂ that attain the highest PCE_{d} are determined, where d₁/Δn₁ are the values for VHLs I and IV and d₂/Δn₂ are the values for VHLs II and III. DCG is assumed as the holographic material and a set of possible film thicknesses between 1 um and 30 um and index modulation up to 0.1 are considered based on the material limitations.

Before simulating the PCE_{d}, the set of index modulation values that provide the highest diffraction efficiency for each film thickness is determined. For a given film thickness, the index modulation that provides the highest diffraction efficiency is determined by simulating the diffraction efficiency for a range of index modulation values within the material limitations and selecting the value that provides the highest diffraction efficiency. Once this is determined, the PCE_{d} is simulated for each film thickness and its corresponding index modulation. The combination of holographic film thickness and index modulation values that provide the highest PCE_{d} is selected as the most optimal combination. The optimizations for d₁/Δn₁ and d₂/Δn₂ are performed separately since these sets of parameters independently affect the PCE_{d}.

### Optimization Example

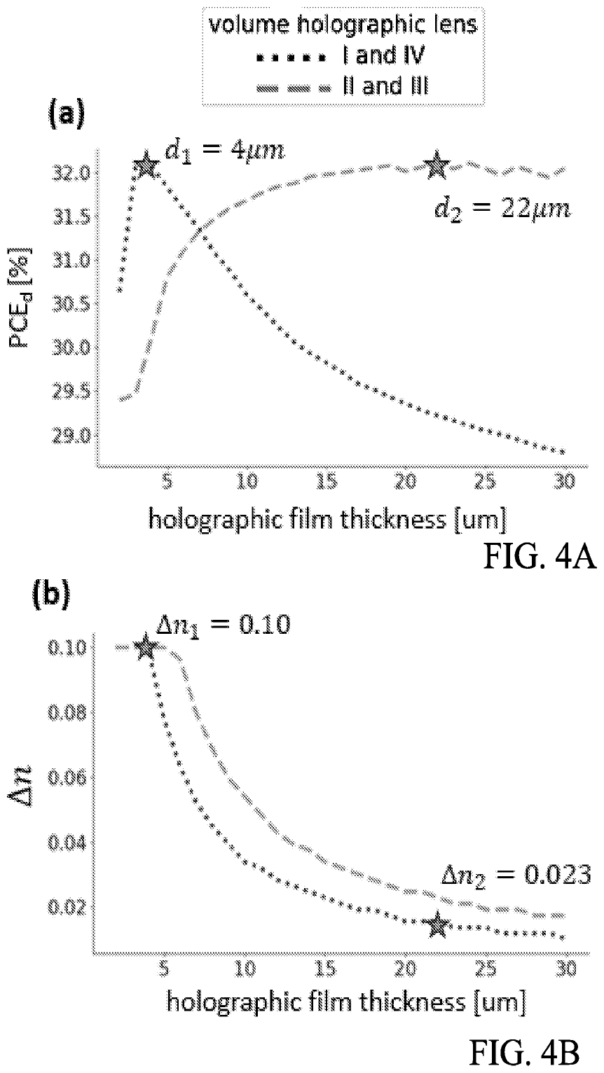

As an example, a VHOE is optimized assuming a CR of 2 and a FAR of 1. First, the construction point sources are determined (Table 1). The point source locations are measured with respect to the center of the VHL. Next the index modulation and holographic film thickness is optimized. FIG. 4(a) shows the PCE_{d} for different film thickness iterations of the VHL optimization. The dotted blue line corresponds to the optimization for VHLs I and IV and the dashed yellow line corresponds to the optimization for VHLs II and III. In both cases the PCE_{d} value is calculated assuming that the other VHLs in the array have already been optimized. The optimal values are d₁=4 um and d₂=22 um. FIG. 4(b) shows the optimal index modulation values corresponding to each holographic film thickness. The optimal index modulation values that correspond to the film thicknesses that attained the highest PCE_{d} are Δn₁=0.1 and Δn₂=0.023.

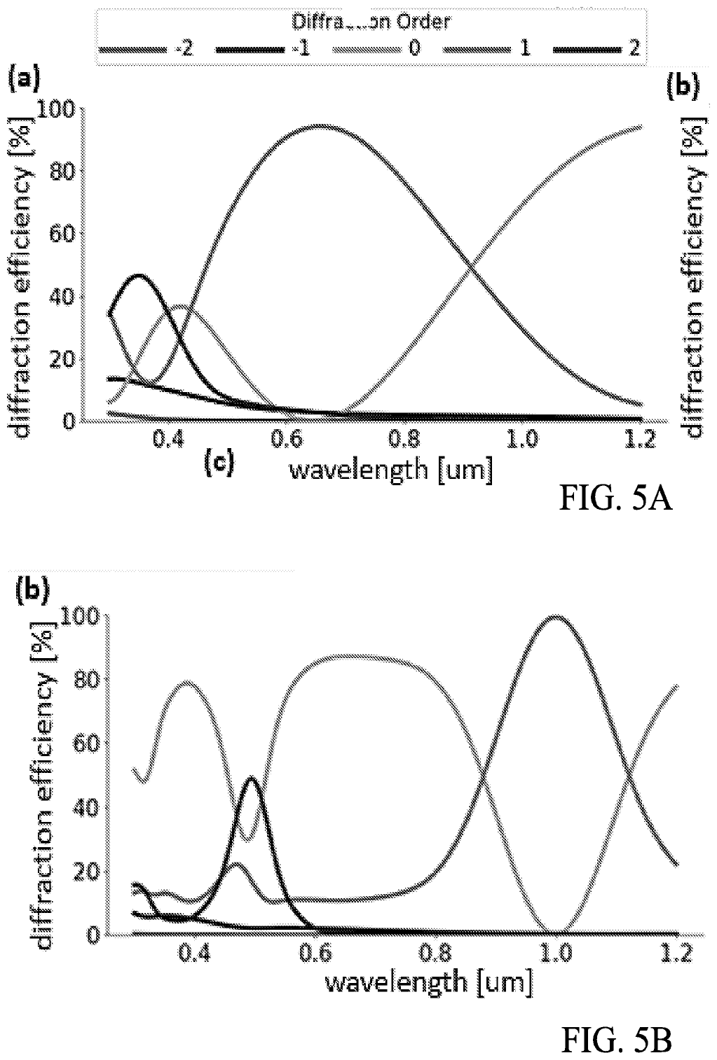

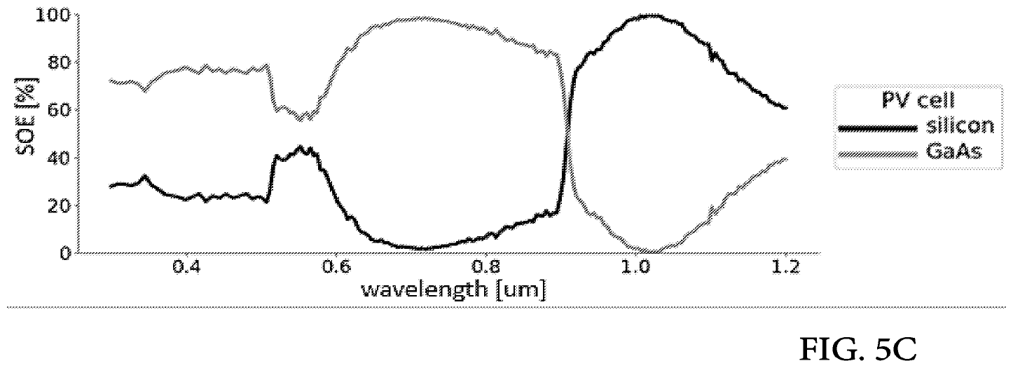

The average spectral diffraction efficiency along the aperture of VHLs I and IV is computed and plotted in FIG. 5(a) and for VHLs II and III in FIG. 5(b). Each grating has a spectral bandwidth covering the majority of the spectral band of interest. The SOEⱼ(λ) of the system is simulated and plotted in FIG. 5(c). Simulations with this algorithm find a solution that produces a sharp spectral cutoff at the transition wavelength (i.e. 0.875 um), with maximum diffraction efficiencies occurring at 0.65 um and 1.0 um. A decrease in the SOE(λ) for GaAs is observed between 0.5 um and 0.6 um due to the onset of higher order diffraction. The noise observed in the SOE(λ) is due to the statistical nature of the Monte Carlo raytrace simulation, but variations in the simulated PCE_{d} are smaller than the precision reported in the present disclosure. The VHOE in this example has a PCE_{d} of 32.0%.

Table 1 shows a list of optimized volume holographic element parameters. The film thickness, index modulation, and point source positions are listed for each of the four VHLs in the unit cell. The point sources positions assume fabrication using a laser with light at wavelength 532 nm and are measured from the center of the respective VHL.

| | I | II | III | IV |
|---|---|---|---|---|
| film thickness [um] | 4 | 22 | 22 | 4 |
| index modulation | 0.1 | 0.023 | 0.023 | 0.1 |
| point source | (2.38, | (1.21, | (−1.21, | (−2.38, |
| position, P1 [cm] | 6.19) | 3.70) | 3.70) | 6.19) |
| point source | (2.52, | (1.26, | (−1.26, | (−2.52, |
| position, P2 [cm] | 68.1) | 12.9) | 12.9) | 68.1) |

FIG. 4 shows graphs for displaying data associated with volume holographic lenses. Graph (a) shows power conversion efficiency for holographic film thicknesses between 1-30 um for a system with CR=2 and FAR=1.0. The yellow dashed curve is for volume holographic lenses (VHL) II and III while the blue dotted curve is for VHLs I and IV. The film thicknesses that achieve the optimal PCE_{d} are marked. The PCE_{d} values shown for VHLs II and III assume that VHLs I and IV have already been optimized and likewise the PCE_{d} values shown for VHLs I and IV assume that VHLs II and III have already been optimized. Graph (b) shows the optimal index modulation for maximizing the diffraction efficiency of the VHL is plotted as a function of the holographic film thickness. The index modulation associated with the optimal film thickness is marked.

FIG. 5 shows graphs for displaying data associated with volume holographic lenses. Graph (a) shows the spectral diffraction efficiency averaged over the apertures of volume holographic lenses (VHL) I and IV, graph (b) shows the spectral diffraction efficiency averaged over the apertures of VHLs II and III, and graph (c) shows the spectral optical efficiency of the system. Since all of the light is directed to one of the two PV cells, the sum of the two SOE curves is equal to 100%.

Annual Energy Yield Analysis

Annual Energy Yield Calculation

The EYₜ, of the system can be computed as the sum of the direct, diffuse, and ground reflected solar insolation components that are converted into electrical energy and are represented as EY_{d}, EYₛ, and EYᵣ respectively:

EYₜ=EY_{d}+EYₛ+EYᵣ #(8)

The direct and diffuse components are computed based on the power conversion efficiency for direct and diffuse illumination, represented as PCE_{d} and PCEₛ, respectively:

EY_{d}=PCE_{d}·E_{d} #(9)

EYₛ=PCEₛ·Eₛ #(10)

where E_{d} and Eₛ are the direct and diffuse solar insolation components from the Typical Meteorological Year (TMY3) database at a specific location. The component of energy yield from light reflected from the ground or scattered from the atmosphere onto the rear-side of the module is determined according to:

EYᵣ=χ·(E_{d}+Eₛ)·PCEᵣ #(11)

where χ is the irradiance factor given by:

χ=Eᵣ/(E_{d}+Eₛ) #(12)

and PCEᵣ is the power conversion efficiency on the rear side of the PV module and E_{d}+Eₛ is the insolation on the front side of the module.

Modeling the rear illumination is a challenging task that depends on factors related to the module spacing, ground clearance, tilt angle, and albedo. In literature, results are not typically reported in terms of the irradiance factor, but instead reported in terms of the bifacial gain:

BG=χ·ϕ #(13)

where ϕ is bifacial factor which is the ratio of the conversion efficiency of the rear side of the module over the front side of the module. The irradiance factor can be obtained from studies in literature simply by dividing the BG by the bifacial factor. In some cases, the bifacial factor is assumed to be 1, so the BG is equivalent to the irradiance factor. The irradiance factor can calculated using the formula by Kutzer et. al.:

χ=α·0.95·[1.037·(1−\sqrt{gcr})·(1−e\hat{ }(−8.691·h·gcr))+0.125·(1−gcr\hat{x}4)] #(14)

where α is the albedo, h is the length of the module, and gcr is the ground coverage ratio, or the ratio of the module length over the distance between modules. According to this model, the irradiance factor varies between 7.3%-18.4% when the albedo varies between 0.2-0.5 for fixed module height h=0.3 m and gcr=0.5. In Pelaez et al. the irradiance factor varies between 10-20%. In the present disclosure, an irradiance factor of 15% is assumed except when otherwise noted. The irradiance factor can further be increased to 30% by elevating the modules to 1 m off the ground and 50% for standalone modules.

The energy yield can also be expressed in terms of the energy conversion efficiency (ECE), or the fraction of the EYₜ over the total insolation incident on the front-side of the module:

ECE=EYₜ/(E_{d}+Eₛ) #(15)

This expression provides a convenient comparison of the performance of systems under different illumination conditions and provides a convenient metric for comparing monofacial and bifacial systems. For example, a monofacial silicon module with cell conversion efficiency ηₛ=22.5% also has an ECE of 22.5%. A bifacial silicon module with ηₛ=22.5% and with BG=15% has an ECE of 25.9%, indicating that a monofacial module must have a PV cell conversion efficiency of ηₛ=25.9% to achieve the same energy yield as the bifacial module.

Conversion of Diffuse Illumination

The power conversion efficiency for diffuse sunlight is determined using a similar raytracing method as for direct sunlight. In the FRED model described in Section 2.2, a Lambertian scattering surface with 100% transmittance is placed underneath the spectral source. The source is designed to simulate diffuse sunlight, propagating towards the VHOE over a steradians. The spectral diffraction efficiency of the VHOE is simulated with a broad range of incidence angles. A raytrace simulation yields the SOEⱼ(λ) for diffuse sunlight and the PCEₛ is computed using the SMARTS2 spectrum for diffuse sunlight with an air mass of 1.5, AM1.5s(λ):

$$P C {E}_{s} = {\sum }_{j} \frac{\int A M 1 . {5}_{s} ( λ ) \cdot {SOE}_{j} ( λ ) \cdot {SCE}_{j} ( λ ) \cdot d λ}{\int AM {1.5}_{s} ( λ ) \cdot d λ} \qquad \# ( 16 )$$

Continuing the example from Section 2.5, a system with a FAR of 1 and CR of 2 obtains a PCEₛ of 24.0%.

Conversion of Rear-Side Illumination

The power conversion efficiency for the rear side of the module is determined in FRED by modifying the unit cell model in Section 2.2. First, a 96% reflective Lambertian scattering surface is placed underneath the GaAs cell to enhance light collection by the bifacial silicon cell. Next, a glass encapsulant layer with thickness, hᵣ, is placed underneath the PV cells. Lastly a source with irradiance, Gᵣ, is placed underneath the glass encapsulant layer. The collection factor (CF) is determined by running a raytrace simulation:

CF=Iₛ/Gᵣ #(17)

where Iₛ is the irradiance absorbed by the bifacial silicon cell. The PCEᵣ is determined by multiplying the CF by the conversion efficiency of the bifacial silicon, ηₛ=22.5%:

PCEᵣ=CF·ηₛ #(18)

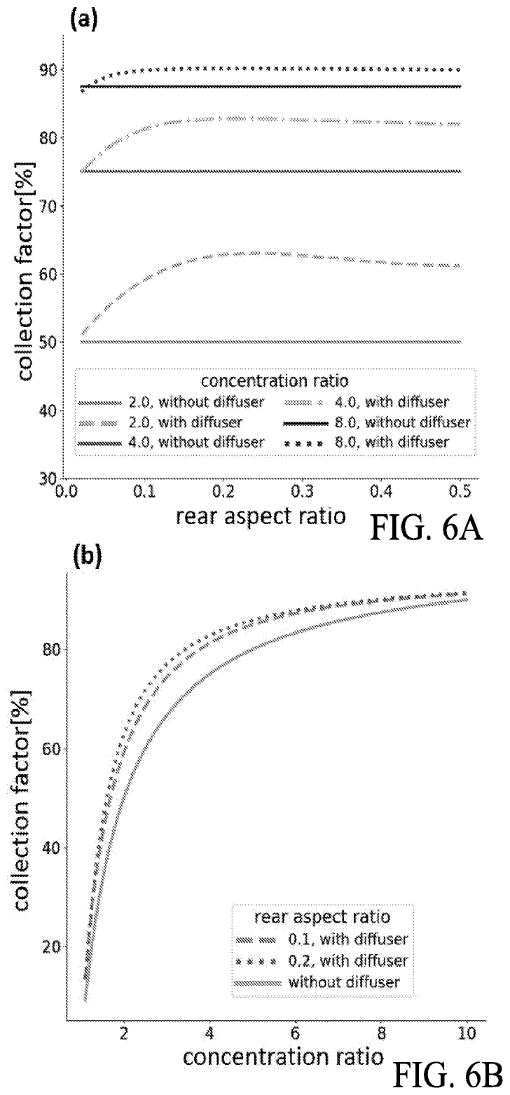

The CF is dependent upon the CR and the RAR as shown in FIGS. 6(a) and 6(b).

The CF depends upon the CR since the system can only convert irradiance in the fraction of the area covered by bifacial silicon cells and cannot convert light in the area filled by the GaAs cell. The CF depends upon the RAR since it affects the average number of passes a ray needs to take through the rear-scattering surface before it hits the silicon cell and is converted. Each pass through the scattering surface loses a percentage of light through the TIR escape cone, so the RAR needs to be large enough to minimize this effect. With a RAR of 0.2, the CF is enhanced by up to 25% with the rear scattering surface. In the remaining parts of this analysis it is assumed that the RAR value is 0.2.

FIG. 6 shows graphs for displaying a fraction of the total rear-side irradiance collected by the bifacial silicon cell, known as the “collection factor”. The collection factor is plotted as a function of (a) rear aspect ratio, and (b) concentration ratio. The results indicate the diffuser provides optimal enhancement when the rear aspect ratio is around 0.2 and when the concentration ratio is near 2.

### Effect of Illumination on Annual Energy Yield

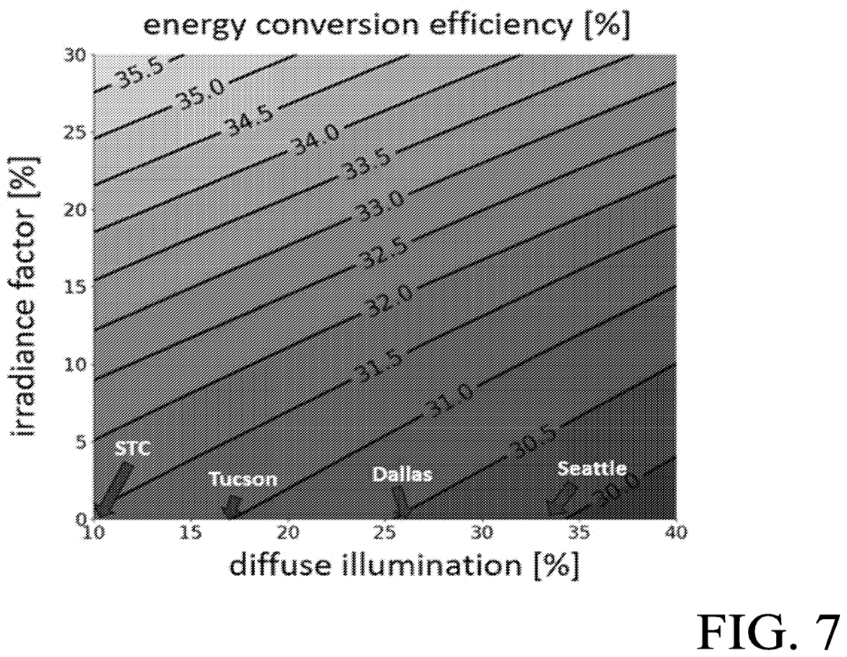

Different locations, ground surface characteristics, and module array geometries result in varying illumination conditions and module performance. To analyze the performance of the module, the EYₜ is computed for different illumination conditions for the example system with a FAR of 1 and CR of 2 and plotted in terms of the ECE in FIG. 7. On the horizontal axis, the ratio of diffuse insolation to front-side insolation is plotted. On the vertical axis the irradiance factor is plotted, which is the ratio of rear-side insolation over total front-side insolation. The percentage of diffuse illumination for different locations and for STC conditions are also indicated. From the plot it can be determined that the system has an STC efficiency of 31.4%, which does not account for any conversion of rear-side illumination. For an irradiance factor of 15%, the system converts 1010(kw·hr)/(yr·m\hat{ }2) in Tucson, Ariz., resulting in an ECE of 32.8%. In Seattle, Wash. the system converts 550(kw·hr)/(yr·m\hat{ }2), resulting in an ECE of 31.5%. While the EYₜ is much lower in Seattle, the primary cause is the lower solar insolation and not the decrease in ECE, which only decreases by 4%.

Using the Kutzner model (Eq. 14) for illumination parameters in Tucson, the irradiance factor varies between 7.3%-18.4% for albedo values ranging between 0.2-0.5, assuming module height h=0.3 m and gcr=0.5. Using FIG. 7, the corresponding ECE for this albedo range is 31.8%-33.5% in Tucson and 30.7%-32.1% in Seattle. In cases where modules are sparsely spaced, highly elevated, or stand alone, the irradiance factor can exceed 30%, resulting in modules ECE values of greater than 35%.

FIG. 7 shows a contour plot of the energy conversion efficiency for different illumination conditions. The diffuse illumination on the horizontal axis is the fraction of diffuse insolation over the total insolation on the front side of the module. The irradiance factor on the vertical axis is the fraction of rear-side insolation over the total insolation on the front side of the module. The diffuse illumination percentage for the locations Tucson, Dallas, and Seattle are marked. Additionally, the STC condition is marked, in which there is 10% diffuse light and no rear-side illumination.

Effect of Sun-Tracking on Energy Yield

The diffraction efficiency of the VHOE is sensitive to the angle of incidence of light. While in the previous EYₜ calculation, we assumed dual-axis tracking systems with no tracking error, most utility-scale PV plants deploy single-axis tracking since it is more economical. To confirm that the BF-SSPV system is compatible with single-axis tracking, the EYₜ for a single-axis tracking system with tracking accuracy of +/−0.5 degrees is evaluated for the example system with a FAR of 1 and a CR of 2.

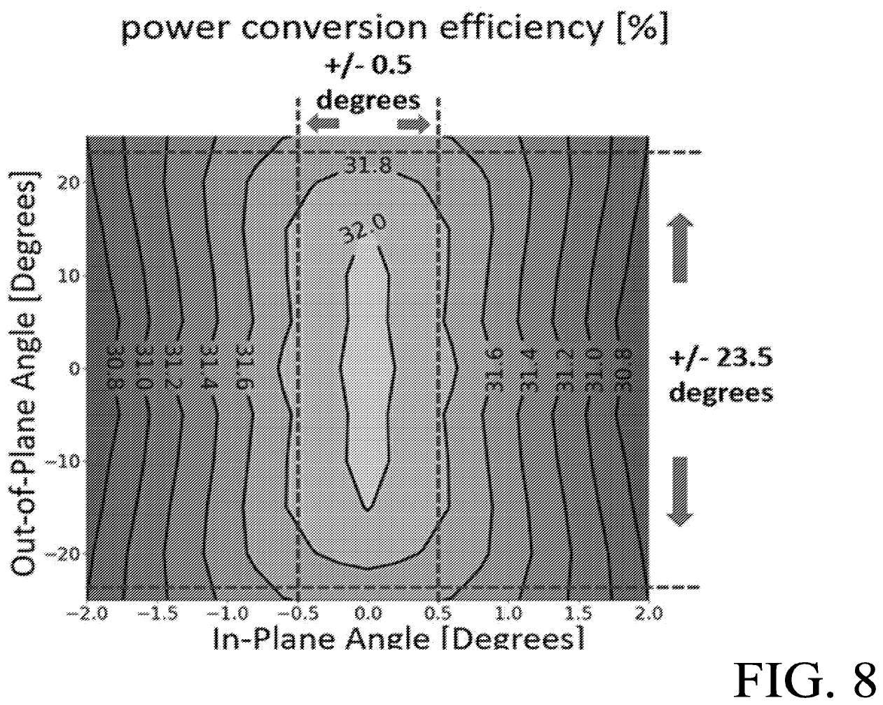

The PCE_{d} is computed over a range of incidence angles using the same simulation method as described in section 2.2, except the source is set at a specified incidence angle and is not normally incident. The results are plotted in a contour plot in FIG. 8. The in-plane angle is plotted along the horizontal axis and the out-of-plane angle is plotted along the vertical axis. The in-plane angle lies in the plane that the surface normal of the module exists in as it tracks the sun from east to west throughout the course of the day. For a single-axis tracking system, the in-plane angle only varies within a small range due to the inaccuracy of the tracking system. The out-of-plane angle lies in the plane of the surface normal and the rotation axis and varies between +/−23.5 degrees throughout the different seasons of the year due to the changing declination angle of the earth. The VHOE is most sensitive to variations in the in-plane angle, while it less sensitive to variations in the out-of-plane angle.

The PCE_{d} is averaged over the range of angles marked in the dotted red box to estimate the average efficiency of the system. For a tracking system with +/−0.5 degree accuracy, the PCE_{d} degrades from 32.0% to 31.9%. The EYₜ computation follows the method described previously, except the direct insolation is reduced since angle of the panel with respect to the sun reduces the irradiance by the cosine factor. The modified value of the direct insolation is determined using a method similar to Zhang et. al. by multiplying each DNI data value by the cosine factor for that data point. The cosine factor is computed as the dot product of the surface normal of the panel and the unit vector pointing in the direction of the sun's position. The cosine factor is calculated for each DNI data point in TMY3 by calculating the sun's position based on the day and hour values that the data point was taken. Using this method, the EYₜ decreases from 1010(kw·hr)/(yr·m\hat{ }2) to 970(kw·hr)/(yr·m\hat{ }2). 90% of the 40(kw·hr)/(yr·m\hat{ }2) loss in energy yield is due to the cosine factor losses and not due to the degraded quality of the optical filtering. From this analysis, it can be seen that the BF-SSPV system can be implemented with single-axis tracking systems with minimal degradation in the energy yield.

FIG. 8 shows an illustration of power conversion efficiency for the direct component of sunlight as a function of incidence angle with respect to the module. The range of incidence angles expected over the course of a year for a one-axis tracking system with tracking accuracy of +/−0.5 degrees is marked by the dotted red lines.

Effect of Unit Cell Dimensions on Energy Yield

The CR and FAR values are important parameters in the BF-SSPV system design since they impact the EYₜ that can be achieved, but also factor into the cost, size, and weight of the system. Typically, the wide-bandgap PV cells in SSPV systems are assumed to be from III-Vs since they have been demonstrated to be manufactured with high conversion efficiency. Unfortunately, III-V cells are relatively expensive compared to silicon cells. For this reason, it is worthwhile analyzing the tradeoffs between EYₜ and CR. Similarly, the FAR affects the thickness of the glass or plastic material layer between the VHOE and the PV cells. A thinner layer is more desirable for reducing the weight and bulkiness of the system, but it comes at the cost of reducing the EYₜ. The CR and FAR values determine the form factor of the unit cell, the optimal VHOE parameters, and the EYₜ that can be achieved. Once these parameters are chosen, the absolute dimensions of the unit cell size can be scaled without any effect on the optimal VHOE parameters or the achievable EYₜ.

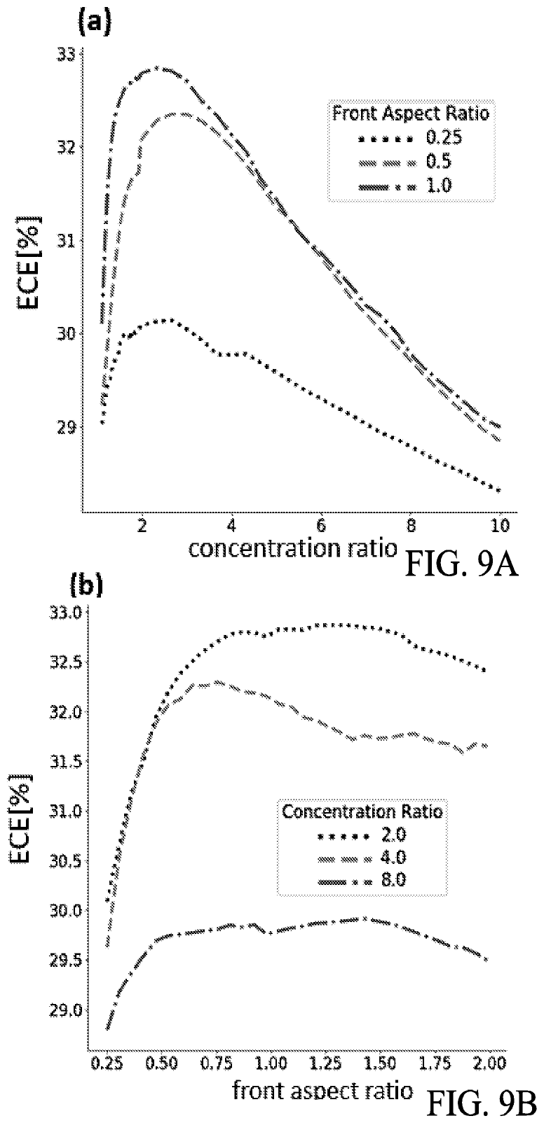

The EYₜ was simulated for a range of CR and FAR values with illumination in Tucson, Ariz. with an irradiance factor of 15%. The results are plotted in terms of the ECE and are shown in FIG. 9. In FIG. 9(a) the ECE is plotted as function of the CR for three different FAR values. The optimal ECE occurs for CR values between 2 and 3 depending on the FAR and even CR values as high as 8 can provide ECE of 30%. In FIG. 9(b) the ECE is plotted as a function of the FAR for three different CR values. FAR values between 0.5 and 1.5 provide the highest ECE, and greater than 30% ECE can be achieved even for thin modules with FAR values as low as 0.25.

FIG. 9 shows graphs for displaying data associated with energy conversion efficiency. Energy conversion efficiency (ECE) for the BF-SSPV system using 22.5% efficient bifacial silicon and 28.8% efficient GaAs cells peaks at ECE=32.8% for illumination in Tucson, Ariz. with an irradiance factor of 15%. (a) ECE is plotted against the concentration ratio on the GaAs cell. The plot indicates optimal performance for concentration ratios between 2 and 3. (b) ECE plotted against the front aspect ratio indicates optimal performance for aspect ratios between 0.5 and 1.5.

Comparison to Other PV Systems

The single-axis tracking EYₜ of the BF-SSPV system is compared to other PV systems in Table 2. The EYₜ in Tucson, Ariz. of each PV system is presented alongside the percent improvement in EYₜ of the BF-SSPV system over each system. The irradiance factor is assumed to be 15% for all systems. The following systems are listed according to energy yield: 1) monofacial silicon with conversion efficiency of 22.5%, 2) bifacial silicon with conversion efficiency of 22.5%, 3) GaAs with conversion efficiency of 28.8%, 4) the SSPV system from Vorndran et. Al (corrected for single-axis tracking), 5) the optimized SSPV system from this paper using monofacial silicon instead of bifacial silicon, 6) the BF-SSPV system example in the present disclosure.

The EYₜ improvement can also be compared for different illumination conditions. For example, using the Kutzner model (Eq. 14) for albedo values between the 0.2-0.5, the improvement of the BF-SSPV over monofacial silicon and monofacial SSPV systems ranges between 40%-47% and 4%-9%, respectively.

Table 2 shows Energy Yield for various PV systems in Tucson, Ariz., assuming the irradiance factor is 15%. The improvement in energy yield of the BF-SSPV system is listed as a percentage.

| | $\begin{matrix}Energy \\ Yield [ \frac{kw \cdot hr}{yr \cdot {m}^{2}} ]\end{matrix}$ | BF-SSPV Improvement [%] |
|---|---|---|
| Monofacial | 670 | 45 |
| silicon | | |
| Bifacial silicon | 770 | 26 |
| GaAs | 850 | 14 |
| Vorndran SSPV* | 870 | 11 |
| Monofacial SSPV | 900 | 7 |
| BF-SSPV | 970 | N/A |

*S.D. Vorndran, B. Chrysler, B. Wheelwright, R. Angel, Z. Holman, and R. Kostuk, ″Off-axis holographic lens spectrum-splitting photovoltaic system for direct and diffuse solar energy conversion,″ Appl. Opt. 55(27), 7522-7529 (2016).

Discussion

Over recent years the market for BFPV has grown rapidly while high-efficiency PV systems such as multijunction CPV have declined. BFPV modules are promising since they increase EYₜ for a relatively small increase in module cost, but this development should not preclude the research and development of high conversion-efficiency modules, as the system design in the present disclosure shows the two approaches for improving EYₜ are not exclusive. Like BFPV modules, SSPV modules have potential for large increases in EYₜ using relatively inexpensive materials. DCG VHOEs cost as little as 3 $/m² and have previously been used in commercially made PV modules by Prism Solar Technologies. As indicated by the tracking analysis in the present disclosure, SSPV modules can be integrated into inexpensive one-axis tracking systems. The greatest obstacle in terms of achieving cost-effective SSPV and BF-SSPV systems is the development of a relatively inexpensive wide-bandgap PV cell, since state-of-the-art III-V cells are orders of magnitude more expensive than silicon. Even wide-bandgap cells that are several times more expensive than silicon may be acceptable since, as shown in the present disclosure, the CR can be engineered to reduce the area filled by the wide-bandgap cell while maintaining high EYₜ.

In recent years, researchers and start-up companies have invested more in replication machines and techniques for mass-manufacturing VHOEs. Roll-to-roll manufacturing has been demonstrated and a variety of hologram copying techniques have been utilized that show how high-efficiency elements can be fabricated with sufficient repeatability. The feasibility of manufacturing and implementing VHOEs in solar applications was demonstrated by Prism Solar Technologies with their holographic solar concentrators, which were successful when the price of silicon was higher. These developments show that the manufacturing of VHOEs for the BF-SSPV system is feasible and scalable for mass-manufacturing.

Further improvements in EYₜ can be obtained by employing a bifacial GaAs cell instead of the monofacial cell used in this analysis. In this configuration no rear scattering reflector would be necessary and light would be converted across the entire aperture of the rear side of the module. The monofacial GaAs cell was used to emphasize that the cells in the present disclosure are commercially available and based on currently achievable cell efficiencies. However, wide-bandgap bifacial GaAs cells have been developed in laboratory conditions and could be implemented in this system, improving the EYₜ of the reported design by 4.8% and outperforming monofacial SSPV systems by 12.3%.

Future work should focus on comparing the advantages, limitations, and feasibility of using different methods for enhancing the optical filter design. For example, the VHOE described in the present disclosure provided optimal spectral bandwidth and filter shape, assuming a single-layer grating with sinusoidal index modulation. While this approach is advantageous for its simplicity relating to the hologram fabrication, other approaches achieve broader bandwidth and a more ideal filter profile. Vorndran et. al. utilized a non-linear swelling effect observed in DCG that broadens the Bragg-matching condition and provides more ideal spectral filtering. In other approaches, Wu et. al. used cascaded VHOEs and Leger et. al used multiplexed VHOEs. In addition to enhanced filtering that can increase EYₜ, cascaded or multiplexed elements can be used to decrease dispersion and may be used to design SSPV systems with higher CR or lower FAR values.

### CONCLUSION

In the present disclosure a photovoltaic system is proposed that achieves high energy yield by combining holographic spectrum-splitting and bifacial photovoltaic technologies. The system comprises an array of volume holographic lenses that splits normally incident sunlight into spectral bands and directs each band to bifacial silicon and GaAs photovoltaic cells. Diffuse sunlight is transmitted through the hologram without diffraction and is converted. Rear-side illumination is converted by the bifacial silicon and the rear-side light collection is enhanced by up to 25% using a reflective scattering surface on the rear-side of the wide-bandgap cell. The energy yield is optimized by tuning the volume holographic element film thickness, index modulation, and construction point source locations. The energy yield is analyzed for a variety of conditions and it is determined that for dual-axis tracking and typical illumination conditions in Tucson, Ariz. the system achieves 32.8% energy conversion efficiency and can exceed 35% under certain illumination conditions. When comparing dual-axis tracking and single-axis tracking, the energy yield decreases from 1010(kw·hr)/(yr·m\hat{ }2) to 970(kw·hr)/(yr·m\hat{ }2) where 90% of the decrease is due to reduced irradiance due to the cosine factor from the earth's changing declination angle throughout the course of the year and not from optical filtering losses. Lastly, it is determined that the optimal concentration ratio is between 2 and 3 but can still reach 30% energy conversion efficiency for values as high as 8. The optimal front aspect ratio lies between 0.5 and 1.5 but the energy conversion efficiency can exceed 30% even for values as low as 0.25. From the analysis in the present disclosure, it is concluded that bifacial cell conversion can be integrated into spectrum-splitting photovoltaic systems, resulting in modules that have conventional forms factors and can be integrated with single-axis tracking and that have higher energy yield than either technology individually achieves.

Photovoltaic solar energy conversion systems are becoming more pervasive as a renewable energy source. However, their cost per watt ($/W) and cost per kilowatt-hour ($/kW-hr) performance is still above that available from fossil fuels. This makes replacement of conventional power sources with solar difficult to justify in certain operating environments. In order to make solar more competitive the conversion efficiency must increase without significant increase to the system cost. Several methods have been proposed to increase the power conversion efficiency of photovoltaic systems. These include: i) broad spectral band optical concentrators [See Matthew Muller, et. al., “A side-by-side comparison of CPV module and system performance,” Prog. Photovoltaics: Res. Appl., Vol. 24, 940-954 (2016)]; ii) spectrum splitting systems that use an optical system to separate different spectral bands and direct the separated spectra to different single bandgap PV cells that maximize the conversion efficiency of the spectral band [See e.g., A. G. Imenes and D. R. Mills, “Spectral beam splitting technology for increased conversion efficiency in solar concentrating systems: a review,” Sol. Energy Mater. Sol. Cells 84(1-4), 19-69 (2004); A. Mojiri, R. Taylor, E. Thomsen, and G. Rosengarten, “Spectral beam splitting for efficient conversion of solar energy—A review,” Renew. Sustain. Energy Rev. 28, 654-663 (2013); WO2016200988A1]; and iii) modules with bifacial PV cells that collect light from both faces of the module allowing the conversion of light reflected from the surroundings as well as light incident directly from the sun [S. Ayala Pelaez, C. Deline, P. Greenberg, J. S. Stein, R. K. Kostuk, “Model and Validation of Single-Axis Tracking with Bifacial PV,” presented at 7th World Conference on Photovoltaic Energy Conversion, Waikoloa, Hi., 2018]. Each method may improve the conversion efficiency, but may also add system complexity and cost. This in turn decreases the system performance metrics of $/W and $/kW-hr. In order to improve these metrics, the conversion efficiency must be maximized in a large variety of operating environments.

In an aspect of the present disclosure, a PV module may be configured to increase conversion efficiency and may operate in a broader range of solar illumination conditions. In the present disclosure, PV modules may comprise spectrum splitting photovoltaic systems and bifacial cells. As an example, spectrum splitting photovoltaic systems may maximize the use of the incident solar spectral power distribution and can collect both direct and diffuse light. As a further example, bifacial cells may collect light on the back surface of the system. Moreover, PV modules of the present disclosure may be configured (optimized) such that a select ratio of spectrum splitting is effected and/or a ratio of bifacial to non-bifacial cells are used. This affords an increase in the overall system power conversion efficiency without significant increase in the system complexity. For instance, bifacial PV systems already require different cell types and module packages than conventional single bandgap PV cell modules and are used with single axis tracking to increase their energy yield. Spectrum splitting may also require special module packaging and single axis tracking. Most of the additional cost of both bifacial and spectrum splitting systems are related to packaging and the tracking system. Therefore increasing the energy yield by using a combination of the two approaches can potentially lower the $/kW-hr metric.

The proposed concept increases the power conversion efficiency and energy yield of photovoltaic systems by using a combination of spectrum splitting and bifacial solar power collection without significant increase to the system cost. This approach can lower the $/W and $/kW-hr of the photovoltaic system and make it more competitive with other power/energy conversion methods.

When configuring a PV module of the present disclosure, one may evaluate baseline system performance such as:
Equivalent BF PV cell module;
Equivalent spectrum splitting module;
Equivalent monofacial module with Alta Devices GaAs PV cells; and/or
Equivalent monofacial module with Sunpower silicon cells.

When configuring a PV module a single axis tracking may be used. Such a single axis tracking supports spectrum splitting system and may increase bifacial PV performance.

The PV module(s) of the present disclosure may comprise holographic optical elements. Additionally or alternatively, a position of a transition wavelength in the spectrum splitting may be configured (e.g., optimized) based on short/long wavelength conversion efficiency. As an example, an optimum transition wavelength focus may not be at the border between a wide band gap (WBG) and a narrow band gap (NBG) PV cell. As a further example, the optimum transition wavelength may also differ from a wavelength between the WBG and NBG peak wavelengths. Increase concentration on the WBG PV cell in the spectrum splitting system may allow larger area BF silicon cells to increase energy yield from the BF PV cells. Further configuration of the PV modules may comprise:
Examining energy yield performance with 10%, 20%, 30% . . . bifaciality factors;
Examining energy yield performance with different albedo values;
Evaluating system performance with different fractions of the backside populated with BFPV, which may reflect the amount of concentration.

A system of the present disclosure may comprise a spectrum splitting system or component. A spectrum splitting system may optimize the utilization of the spectral content of the incident solar illumination by directing appropriate spectral components to photovoltaic cells that have an increased (or optimized) response to these components. As an example, a spectrum splitting system may comprise holographic optical elements that may be configured to direct incident energy having a first wavelength (or within a first band) to a first PV cell or cells, and direct incident energy having a second wavelength (or in a second band) to a second PV cell or cells. Δn incident surface of the PV module may comprise one or a plurality of spectrum splitting systems. Each of the one or more spectrum splitting systems may comprise a holographic optical element or other device configured to split and direct incident energy based on certain properties (e.g., wavelength). A plurality of spectrum splitting systems may be configured to split or direct incident energy based on different properties such as a different wavelengths or bands. As such, the type of PV cells and the configuration of the spectrum splitting systems may be configured (e.g., tuned) based on conditions or optimization goals.

A rear side of the module may also convert solar illumination that is reflected or scattered from the ground and other objects through the use of bifacial photovoltaic cells on part or all of the rear side of the module surface.

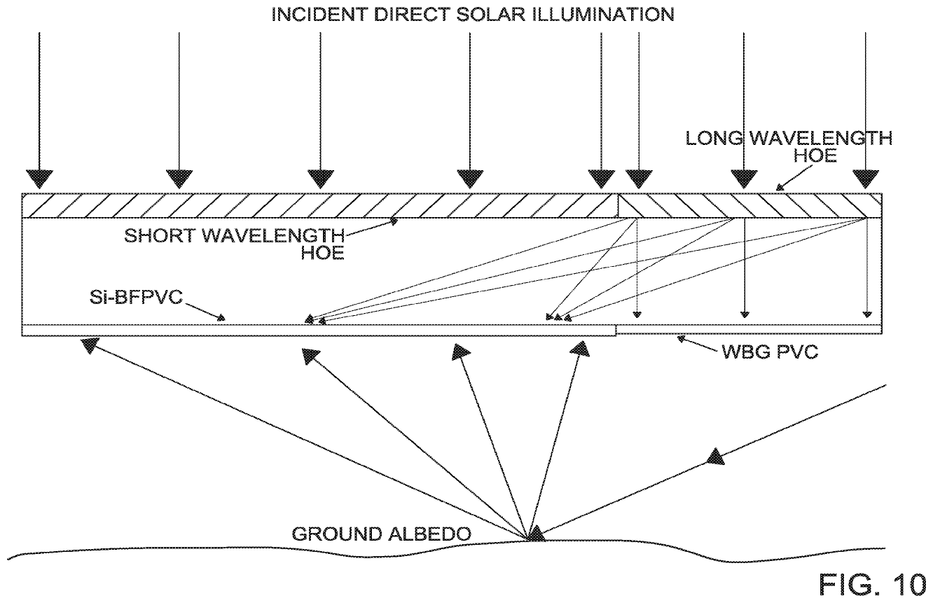

An illustration of one configuration is shown in FIG. 10, for example. As shown, only the silicon cell is bifacial. The wide bandgap (WBG) cell is not bifacial in this case; however in other configurations it can be made bifacial. As shown, incident energy to the long wavelength holographic optical element (HOE) is split and directed based on wavelength—where blue light is allowed to pass through to the WBG PV cell and red light is directed to the Si-BF PV cell. Intermediate light such as green light is directed to a location between the red and blue light. Similarly, a short wavelength HOW may allow red light to pass through to the Si-BF PV cell, while blue light is directed to the WBG PV cell. Such splitting concentrates certain light to the appropriate PV cell. Moreover, the placement of the HOE and the respective PV cells may be configured to optimize performance.

The combined energy yield of the spectrum splitting and bifacial components of the system are optimized together to produce the highest overall system energy yield. Estimated energy yield performance improvement is 4.79% with respect to monofacial spectrum splitting systems; 37.2% with respect to standard bifacial PV, and 55.78% with respect to high performance monofacial silicon PV modules. Based on some preliminary calculations the bifacial spectrum splitting (BFSS) module shows improvement over monofacial spectrum splitting:

Improvements offered with BFSS system with ideal spectrum splitting optical elements:
4.75% with respect to monofacial spectrum splitting systems with ideal spectrum splitting filters;
8.78% with respect to monofacial spectrum splitting systems with experimental spectrum splitting filters;
37.6% with respect to silicon bifacial PV systems (Prism Solar Tech Bi-60 modules with 22.5% efficiency);
55.7% with respect to Sunpower X-Series monofacial silicon modules with 22.8% efficiency.

The efficiency of the bifacial spectrum-splitting system with 50/50 narrow bandgap (silicon) and wide bandgap (GaAs) cells and the silicon cell area bifacial is estimated at 35.5% and if the total backside is bifacial the efficiency increases to 37.19%.

Preliminary results from the hologram optimization modelling is showing improvement with designs that are not 50/50 split between the silicon bifacial and Ga As cells. The modules may be packaged with glass on both the front and rear side and may be used with one-axis tracking. Silicon PV cells may be used. Ga As PV cells may be used. Other PV cells may be used.

1. A photovoltaic module comprising:
one or more spectrum splitting devices disposed adjacent a first side of the photovoltaic module; and
a plurality of photovoltaic cells disposed adjacent a second side of the photovoltaic module opposite the first side and such that the photovoltaic cells are spaced from the one or more spectrum splitting devices,
wherein at least one of the photovoltaic cells disposed adjacent a first side comprise a bifacial photovoltaic cell and at least one or more of the photovoltaic cells disposed adjacent a second side comprise a wide-bandgap cell,
wherein the one or more spectrum splitting devices are configured to selectively direct incident energy to one or more of the photovoltaic cells, and
wherein a spatial configuration of the one or more spectrum splitting devices and the plurality of photovoltaic cells are configured based on an optimization parameter.

2. The photovoltaic module of claim 1, wherein the at least one of the spectrum splitting devices comprises a holographic optical element.

3. The photovoltaic module of claim 1, wherein the at least one of the spectrum splitting devices is configured to allow a first wavelength band to pass there through and is further configured to diffract a second wavelength band.

4. The photovoltaic module of claim 1, wherein one or more of the photovoltaic cells comprises a silicon cell.

5. The photovoltaic module of claim 1, wherein one or more of the photovoltaic cells disposed adjacent a second side comprises a GaAs cell.

6. The photovoltaic module of claim 1, wherein the photovoltaic module is configured for one-axis tracking.

7. The photovoltaic module of claim 1, wherein a selection of the type of photovoltaic cell of one or more of the plurality of photovoltaic cells is based on the optimization parameter.

8. The photovoltaic module of claim 1, wherein the optimization parameter is energy yield.

9. A method of making the photovoltaic module of claim 1.

10. A method of using the photovoltaic module of claim 1.

11. A system comprising
a plurality of bifacial photovoltaic cells; and
an array of volume holographic lenses configured to split normally incident sunlight into a plurality of spectral bands and to direct each of the spectral bands to the bifacial photovoltaic cells,
wherein diffuse sunlight is transmitted through the hologram without diffraction and is converted.

12. The system of claim 11, wherein one or more of the bifacial photovoltaic cells comprises a silicon cell.

13. The system of claim 11, wherein one or more of the bifacial photovoltaic cells comprises a GaAs cell.

14. The system of claim 11, wherein the bifacial photovoltaic cells comprise a silicon cell and GaAs photovoltaic cells.

15. The system of claim 14, wherein rear-side illumination is converted by the bifacial silicon and the rear-side light collection is enhanced using a reflective scattering surface on a rear-side of at least one of the bifacial photovoltaic cells.

16. The system of claim 11, wherein energy yield is optimized by tuning one or more characteristics of the volume holographic lenses.

17. The system of claim 16, wherein the one or more characteristics comprise film thickness, index modulation, or construction point source locations, or a combination thereof.

18. The system of claim 11, wherein the system is configured for one-axis tracking.

19. A method of making the system of claim 11.

20. A method of using the system of claim 11.
